(19) United States
(12) Patent Application Publication
(10) Pub. No.: US 2025/0316958 A1
(43) Pub. Date: Oct. 9, 2025

(54) LASER DIODE COMPONENT AND METHOD FOR PRODUCING AT LEAST ONE LASER DIODE COMPONENT

(71) Applicant: ams-OSRAM International GmbH, Regensburg (DE)

(72) Inventor: Sven GERHARD, Alteglofsheim (DE)

(21) Appl. No.: 18/876,816

(22) PCT Filed: Jun. 14, 2023
(86) PCT No.: PCT/EP2023/065964

§ 371 Date: Dec. 19, 2024

(30) Foreign Application Priority Data
Jun. 23, 2022 (DE) 10 2022 115 644.3

(51) Int. Cl. H01S 5/10; H01S 5/0234; H01S 5/042

(52) U.S. Cl. CPC H01S 5/1021; H01S 5/0421; H01S 5/0234

(57) ABSTRACT

A laser diode component includes a semiconductor layer stack having first and second semiconductor regions, and an active zone between the first and second semiconductor regions. The laser diode component also includes a first contact structure including a first contact element. The laser diode component further includes a second contact structure including a second contact element. The second contact element is on the same side of the laser diode component as the first contact element. The laser diode component additionally includes a resonator including a first resonator region having a first reflective layer on the semiconductor layer stack, and a second resonator region having a first reflective layer and a second, electrically conductive reflective layer, each arranged on the semiconductor layer stack. The second, electrically conductive reflective layer connects the first contact element to the first semiconductor region or the second contact element to the second semiconductor region.

The disclosure relates to a laser diode component and a method for producing at least one laser diode component. For example, the laser diode component is suitable for emitting coherent radiation, for example in the ultraviolet to infrared spectral range.

For example, edge-emitting laser diode components are known which can be electrically connected by means of a top and bottom contact on two different sides of the laser diode component. However, for assembly, especially of advanced components, it can be advantageous for both contacts to be arranged on one side, giving the component a flip-chip design. However, this can be a complex process if it requires further etching and coating steps.

One object to be achieved by the present disclosure is, inter alia, to specify a laser diode component having a flip-chip design. Another object to be achieved by the present disclosure is, inter alia, to specify an efficient method for producing such a laser diode component.

These objects are achieved, inter alia, by a laser diode component and a method for producing at least one laser diode component having the features of the independent claims.

Further advantages and configurations of a laser diode component and of a method for producing at least one laser diode component are the subject of the dependent claims.

According to at least one embodiment of a laser diode component, the laser diode component comprises at least one semiconductor layer stack comprising a first semiconductor region, a second semiconductor region, and an active zone arranged between the first and second semiconductor regions for emitting or generating laser radiation, i.e. coherent radiation.

The active zone can comprise a sequence of individual layers by means of which a quantum well structure, in particular a single quantum well (SQW) structure or multiple quantum well (MQW) structure, is formed.

The first semiconductor region can comprise a first conductivity type, for example a p-type conductivity. Furthermore, the second semiconductor region can comprise a second conductivity type, for example an n-type conductivity. The first and second semiconductor regions can each comprise a sequence of individual layers, some of which can be undoped or lightly doped. The individual layers may be layers epitaxially deposited on a growth substrate.

Materials based on arsenide, phosphide or nitride compound semiconductors, for example, can be considered for the semiconductor regions or individual layers of the semiconductor layer stack. “Based on arsenide, phosphide or nitride compound semiconductors” means in the present context that the semiconductor layers contain AlₙGaₘIn₁₋ₙ₋ₘAS, AlₙGaₘIn₁₋ₙ₋ₘP, InₙGa₁₋ₙAsₘP₁₋ₘ or AlₙGaₘIn₁₋ₙ₋ₘN, with 0≤n≤1, 0≤m≤1 and n+m≤1. This material does not necessarily have to have a mathematically exact composition according to the above formula. Rather, it can include one or more dopants as well as additional constituents that essentially do not change the characteristic physical properties of the AlₙGaₘIn₁₋ₙ₋ₘAs, AlₙGaₘIn₁₋ₙ₋ₘP, InₙGa₁₋ₙAsₘP₁₋ₘ or AlₙGaₘIn₁₋ₙ₋ₘN material. For the sake of simplicity, however, the above formula only contains the essential constituents of the crystal lattice (Al, Ga, In, As or P or N), even if these may be partially replaced by small amounts of other substances. A quinternary semiconductor consisting of Al, Ga, In (group III) and P and As (group V) is also conceivable.

According to at least one embodiment, the laser diode component comprises at least one first contact structure for electrically contacting the first semiconductor region, said first contact structure comprising at least one first contact element, and at least one second contact structure for electrically contacting the second semiconductor region, said second contact structure comprising at least one second contact element, wherein the at least one second contact element is arranged on the same side of the laser diode component as the at least one first contact element. In other words, the laser diode component can have a flip-chip design. The flip-chip design simplifies, for example, integration of the laser diode component into ICs (integrated circuits) or mounting on a carrier with waveguide, for example to combine multiple colors.

According to at least one embodiment, the laser diode component comprises at least one resonator comprising a first resonator region and a second resonator region. The first resonator region can comprise a first reflective layer arranged on the at least one semiconductor layer stack. Furthermore, the second resonator region can comprise a first reflective layer and a second, electrically conductive reflective layer, each of which is arranged on the at least one semiconductor layer stack. In the present disclosure, a “reflective layer” means, for example, a layer which has a reflectivity of at least 10%, preferably of at least 20%, particularly preferably of at least 70%, for the laser radiation generated in the active zone. For example, the first resonator region is arranged at a radiation outcoupling side of the laser diode component. Furthermore, the second resonator region can be arranged on a side of the laser diode component opposite the radiation outcoupling side. The first reflective layers can each comprise alternately arranged layers of a higher and a lower refractive index. For example, the first reflective layers are each a Bragg mirror.

According to at least one embodiment, the at least one first contact element is electrically conductively connected to the first semiconductor region or the at least one second contact element is electrically conductively connected to the second semiconductor region by means of the second, electrically conductive reflective layer. In particular, the second, electrically conductive reflective layer establishes an electrical connection between the semiconductor region which is further away from the side on which the contact elements are located and the associated contact element. As a result, a laser diode component with a flip-chip design can be realized in an advantageous manner. Furthermore, production of the laser diode component is less complex and faster due to the use of the second reflective layer as an electrical connection layer.

For example, a layer of the more distant semiconductor region directly adjacent to the second reflective layer can comprise a higher doping than the rest of the semiconductor region. This can improve the electrical contact.

According to at least one embodiment of a laser diode component, the laser diode component comprises:
at least one semiconductor layer stack comprising a first semiconductor region, a second semiconductor region, and an active zone arranged between the first and second semiconductor regions for emitting laser radiation,
at least one first contact structure for electrically contacting the first semiconductor region, said first contact structure comprising at least one first contact element,
at least one second contact structure for electrically contacting the second semiconductor region, said second contact structure comprising at least one second contact element, wherein the at least one second contact element is arranged on the same side of the laser diode component as the at least one first contact element, and
at least one resonator comprising
   a first resonator region comprising a first reflective layer arranged on the at least one semiconductor layer stack,
   a second resonator region comprising a first reflective layer and a second, electrically conductive reflective layer, each arranged on the at least one semiconductor layer stack, wherein
      the second, electrically conductive reflective layer electrically conductively connects the at least one first contact element to the first semiconductor region or the at least one second contact element to the second semiconductor region.

According to at least one embodiment or configuration, the at least one semiconductor layer stack comprises a first main surface and a second main surface opposite the first main surface, as well as a first side surface and a second side surface opposite the first side surface. The first and second side surfaces may each extend transverse to the first and second main surfaces at least in regions. Starting from the first main surface and extending beyond the active zone, the first and second side surfaces can each extend transverse, in particular substantially perpendicular, to the first and second main surfaces, where “substantially” in the present disclosure means “within the scope of usual manufacturing tolerances”. The first and second side surfaces may each have a substantially horizontal section in the second semiconductor region and, at the transition to the second main surface, may each run transverse, substantially perpendicular, to the first and second main surfaces. As a result, the semiconductor layer stack may comprise a first side region which, in plan view of the laser diode component, protrudes beyond the first main surface in a first lateral direction, and a second side region which, in plan view of the laser diode component, protrudes beyond the first main surface in a second lateral direction. The semiconductor layer stack can comprise further protruding side regions in further lateral directions.

For example, the first resonator region is located at the first side surface and preferably covers a structured region of the semiconductor layer stack, while the second resonator region is located at the second side surface and preferably also covers a structured region of the semiconductor layer stack. The structured regions can be located in vertical sections of the side surfaces.

The first and second main surfaces may delimit the semiconductor layer stack in directions substantially transverse, in particular substantially perpendicular, to a main extension plane of the semiconductor layer stack, while the first and second side surfaces may delimit the semiconductor layer stack at least in regions in directions substantially parallel to the main extension plane of the semiconductor layer stack.

According to at least one embodiment or configuration, the laser diode component is an edge-emitting laser diode component. In this case, radiation is emitted substantially parallel to a plane of the active zone(s) of the laser diode component. The laser diode component can comprise a ridge structure at the first main surface for lateral wave guidance.

According to at least one embodiment or configuration, the first reflective layer of the first resonator region and the first reflective layer of the second resonator region form a continuous layer. This means that all regions of the first reflective layers are connected to each other.

According to at least one embodiment or configuration, the continuous layer is arranged on all side surfaces of the at least one semiconductor layer stack. The at least one semiconductor layer stack may, for example, have an at least approximately cuboid shape and thus four side surfaces. All four side surfaces in each case can be partially or completely covered by the continuous layer.

According to at least one embodiment or configuration, the at least one semiconductor layer stack comprises etching traces at the second side surface in parts covered by the second resonator region. In particular, the etching traces are the result of producing the at least one semiconductor layer stack or the second side surface by means of etching. Accordingly, the at least one semiconductor layer stack may also comprise etching traces at the first side surface in parts covered by the first resonator region. The structured regions mentioned above may therefore be etched regions. However, it is also possible that the first side surface is produced by breaking.

By producing the structured regions by etching, the reflective layers can already be applied on the semiconductor layer stack in a wafer composite. It is not necessary to split the wafer composite in advance, for example by breaking, to produce the side surfaces, which makes the production process less complex as a whole.

According to at least one embodiment or configuration, the first reflective layers are spaced from each other at the first main surface by a gap in which the at least one first contact element or a part of the second reflective layer is arranged.

The first reflective layers may each be electrically weakly conductive or electrically insulating. In this case, the first reflective layer of the second resonator region can have the function of an insulation layer, which electrically insulates a pn junction of the active zone from the electrically conductive second reflective layer.

According to at least one embodiment or configuration, the first reflective layers each comprise a dielectric layer or dielectric layer sequence. Suitable materials for the dielectric layer or dielectric layer sequence are, for example, HfO, Zro, TaO, SiN, SiO, SiON, AlO, AlON, NbO. The first reflective layers can have the same material and layer structure. However, it is also possible for the first reflective layers to be formed from different materials and/or with different layer structures, for example to achieve different reflectivities.

According to at least one embodiment or configuration, the second reflective layer may comprise a metallic layer or metallic layer sequence or consist of a metallic layer or metallic layer sequence. A “metallic layer” or a “metallic layer sequence” is understood to mean, for example, a layer or layer sequence with metallic properties. For example, Ag, Ti, TiW, Rh, Au, Pt or combinations of these materials can be considered for the metallic layer or metallic layer sequence.

According to at least one embodiment or configuration, the second resonator region has a higher reflectivity for the laser radiation than the first resonator region. For example, the first resonator region can have a reflectivity of between 70% and 80% in a wavelength range of 410 nm to 470 nm, while the second resonator region can have a reflectivity of at least 95% in this wavelength range.

According to at least one embodiment or configuration, the second reflective layer is arranged at least partially on a side of the first reflective layer of the second resonator region facing away from the semiconductor layer stack. In particular, in the second resonator region the second reflective layer is arranged on a side of the first reflective layer facing away from the semiconductor layer stack.

According to at least one embodiment or configuration, the second reflective layer extends from the second semiconductor region over the second side surface to the first main surface. A lateral extension of the second reflective layer may be greater than a lateral extension of the ridge structure and less than or equal to a lateral extension of the second side surface.

According to at least one embodiment or configuration, the second reflective layer is arranged on at least one further side surface different from the first and second side surfaces and may have a lateral extension which is less than or equal to a lateral extension of the relevant side surface.

According to at least one embodiment or configuration, the laser diode component comprises a passivation layer arranged on the second reflective layer. The passivation layer is intended, for example, to protect the second reflective layer, which may be formed from a comparatively reactive material such as Ag. The passivation layer can be a dielectric layer, for which materials such as Sio, SiN, SiON, Zro, DLC (diamond-like carbon), SiC, AlN, HfO and NbO can be considered.

According to at least one embodiment or configuration, the at least one first and second contact elements are arranged on the first main surface or on the second main surface. For example, the at least one first and second contact elements can be arranged next to each other, i.e. not overlapping, in plan view of the main surface on which they are arranged. The contact elements can each be strip-shaped, L-shaped or U-shaped. The ridge structure can be covered by at least one of the contact elements at least in regions.

For the at least one first and second contact elements, in each case electrically conductive materials such as Ti, Pt, Au, Zno, TiW, Pd, Rh or combinations thereof can be considered.

According to at least one embodiment or configuration, the laser diode component comprises at least two semiconductor layer stacks spaced from each other by a gap. In one possible configuration, the one semiconductor layer stack adjacent to the gap is used to generate laser radiation, while the other semiconductor layer stack adjacent to the gap is not intended to generate laser radiation. In this case, the second resonator region of the semiconductor layer stack intended for radiation emission can be arranged in the gap. A resonator length of the resonator can be adjusted in a targeted way by means of a suitable positioning of the gap.

According to at least one embodiment or configuration, the laser diode component comprises at least two semiconductor layer stacks which can be provided for emitting laser radiation, wherein the at least two semiconductor layer stacks are provided with a common first resonator region. The second resonator regions can be separate regions or also form a common region. In the case of a common second resonator region, the laser diode component comprises, in particular, a common second reflective layer and a common contact element.

The method described below is suitable for the production of at least one laser diode component of the above-mentioned type. Features described in connection with the laser diode component can therefore also be used for the method and vice versa.

According to at least one embodiment of a method for producing at least one laser diode component of the above-mentioned type, the method comprises the following steps:
providing a semiconductor layer sequence comprising a first semiconductor layer, a second semiconductor layer, and an active layer arranged between the first semiconductor layer and the second semiconductor layer,
structuring the semiconductor layer sequence, wherein at least one semiconductor layer stack is produced comprising a first semiconductor region, a second semiconductor region, and an active zone arranged between the first and second semiconductor regions for emitting laser radiation,
applying at least one first initial reflective layer on the semiconductor layer sequence for producing first reflective layers of a first resonator region and a second resonator region of at least one resonator of at least one laser diode component,
applying at least one second, electrically conductive initial reflective layer on the semiconductor layer sequence for producing at least one second, electrically conductive reflective layer of the second resonator region of at least one resonator of at least one laser diode component,
producing at least one first contact element of at least one first contact structure for electrically contacting the first semiconductor region and at least one second contact element of at least one second contact structure for electrically contacting the second semiconductor region of at least one laser diode component, wherein the at least one second contact element is arranged on the same side of the at least one semiconductor layer stack as the at least one first contact element, and wherein the second initial reflective layer is arranged on the semiconductor layer sequence in such a way that it electrically conductively connects the at least one first contact element to the first semiconductor region or the at least one second contact element to the second semiconductor region.

The steps can be carried out in the specified order.

The semiconductor layer sequence corresponds, in particular with regard to its layer structure and material composition, to the semiconductor layer stack which is produced from it, so that what has been specified in this regard applies accordingly to the semiconductor layer sequence. Preferably, the first semiconductor region is formed from the first semiconductor layer, the active zone is formed from the active layer, and the second semiconductor region is formed from the second semiconductor layer. The semiconductor layer sequence can be provided on a substrate on which it is grown epitaxially, for example.

The first initial reflective layer(s) correspond(s), in particular with regard to its/their layer structure and its/their material composition, to the first reflective layer(s) produced from it/them, so that what has been specified in this regard applies accordingly to the first initial reflective layer(s). Furthermore, the second initial reflective layer(s) correspond(s), in particular with regard to its/their layer structure and its/their material composition, to the second reflective layer(s) produced from it/them, so that what has been specified in this regard applies accordingly to the second initial reflective layer(s).

According to at least one embodiment or configuration, the semiconductor layer sequence is structured by means of etching, wherein at least a part of a first side surface and at least a part of a second side surface of the at least one semiconductor layer stack are produced when etching. The etching step may, for example, include a first etching process, which in particular includes a plasma etching process using chlorine and argon ions, a laser ablation process or a photochemical wet etching process. The etching step may further include a second etching process, in which in particular wet chemical etching is carried out using, for example, KOH, NaOH, NH₄OH, LiOH, TMAH, NMP (N-methyl-2-pyrrolidone) and preferably the first and second side surfaces are smoothed. By means of the second etching process, crystal planes of the material system used for the semiconductor layer sequence can be carved out, which are particularly suitable as laser facets.

According to at least one embodiment or configuration, the structuring of the semiconductor layer sequence is carried out starting from a side of the first semiconductor layer facing away from the second semiconductor layer, through the semiconductor layer sequence and into the second semiconductor layer. In particular, a depth of the structuring determines a vertical extension of a structured region of the respective side surface. The depth or vertical extension indicates, for example, an extension substantially parallel to a vertical direction that runs perpendicular to the main extension plane.

Preferably, the semiconductor layer sequence is not completely penetrated in the vertical direction during structuring, i.e. it is not split, which, in contrast to breaking, enables further processing in the wafer composite. The production process can be simplified as a result.

According to at least one embodiment or configuration, in the first initial reflective layer at least one gap is produced, in which the at least one first contact element or a part of the second initial reflective layer is arranged.

The laser diode component is particularly suitable for AR (augmented reality) and VR (virtual reality) applications as well as for projection and lighting applications.

Further advantages, advantageous embodiments and further developments will become apparent from the exemplary embodiments described below in conjunction with the figures.

In the figures:

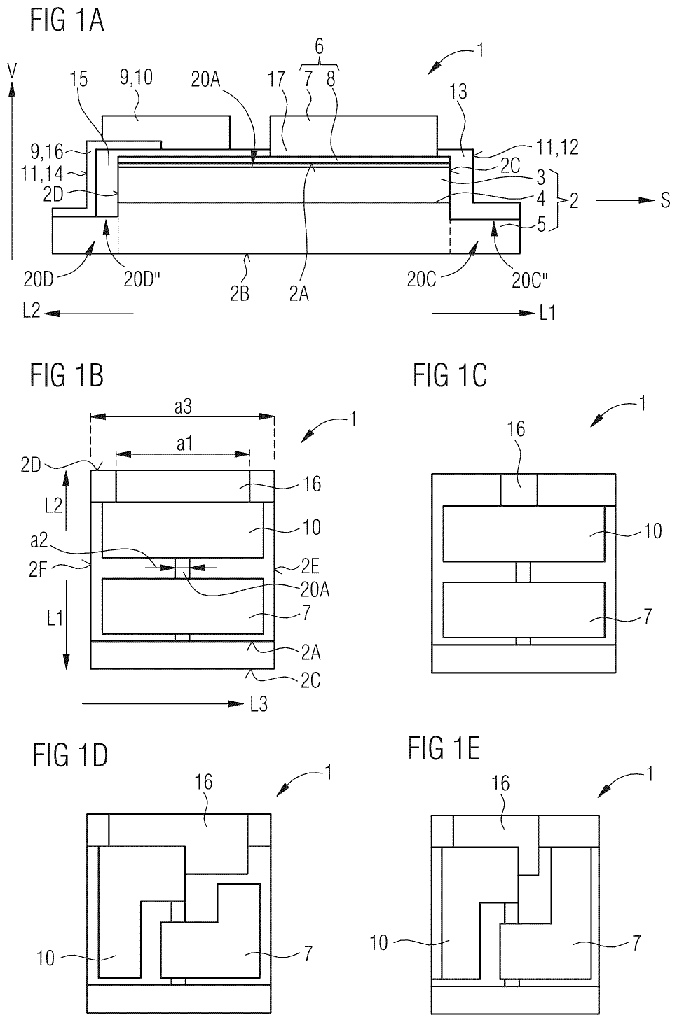

FIG. 1A shows a schematic cross-sectional view, and FIGS. 1B to 1E show schematic top views of exemplary embodiments of a laser diode component which has a cross-sectional view as shown in FIG. 1A in each case,

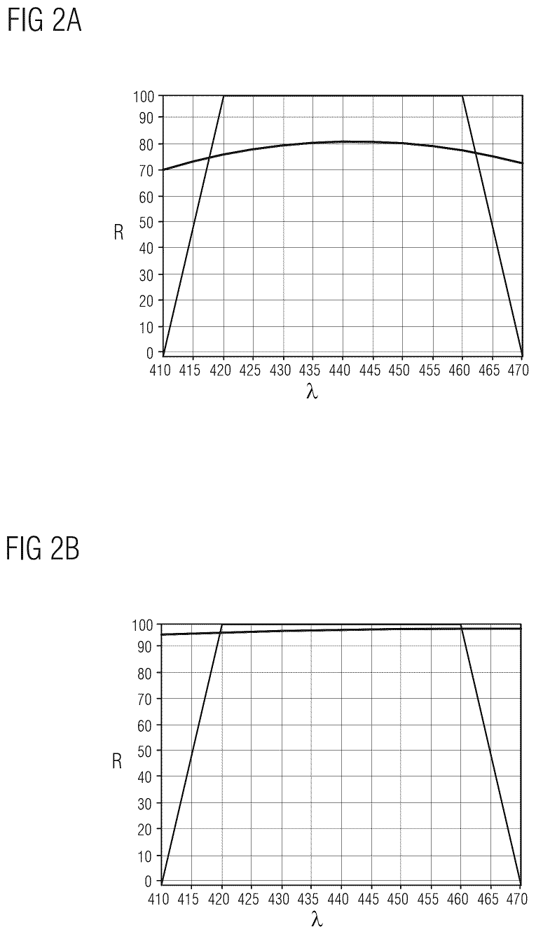

FIG. 2A shows a diagram of the reflectivity of a first reflective layer, and FIG. 2B shows a diagram of the reflectivity of a first reflective layer combined with a second reflective layer,

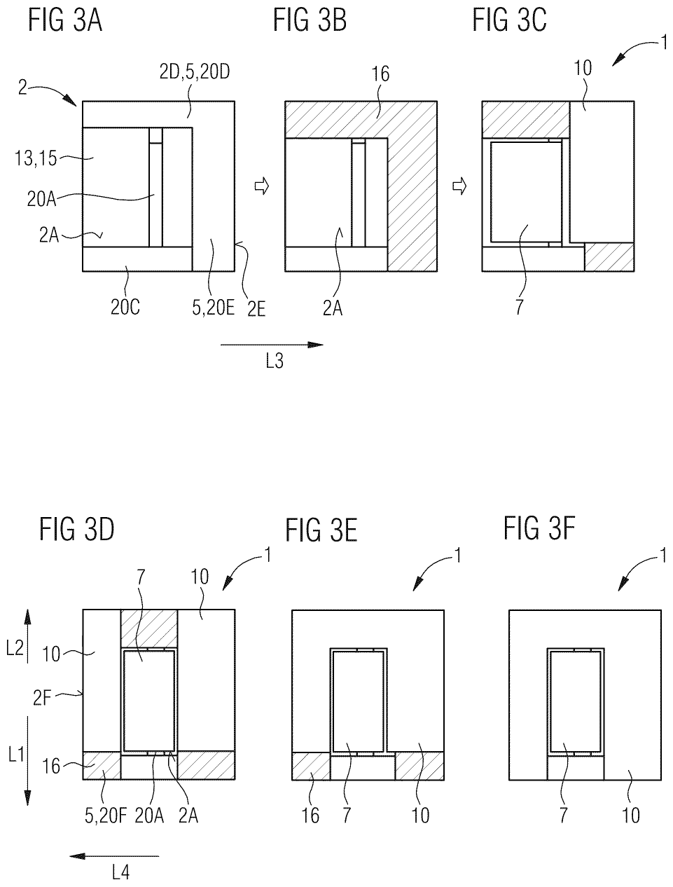

FIG. 3C shows a schematic top view of an exemplary embodiment of a laser diode component, and FIGS. 3A and 3B show schematic top views of intermediate products of the laser diode component, and FIGS. 3D to 3F show schematic top views of further exemplary embodiments of a laser diode component,

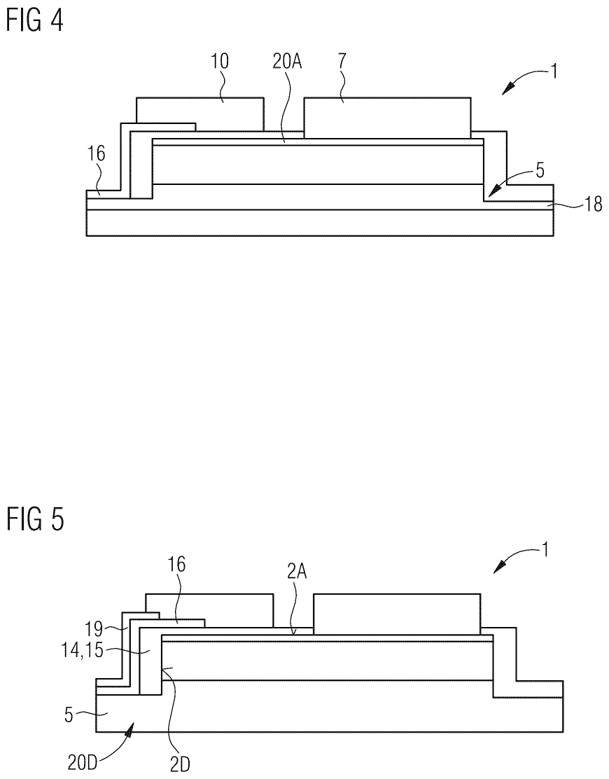

FIGS. 4 to 7 show schematic cross-sectional views of various exemplary embodiments of a laser diode component,

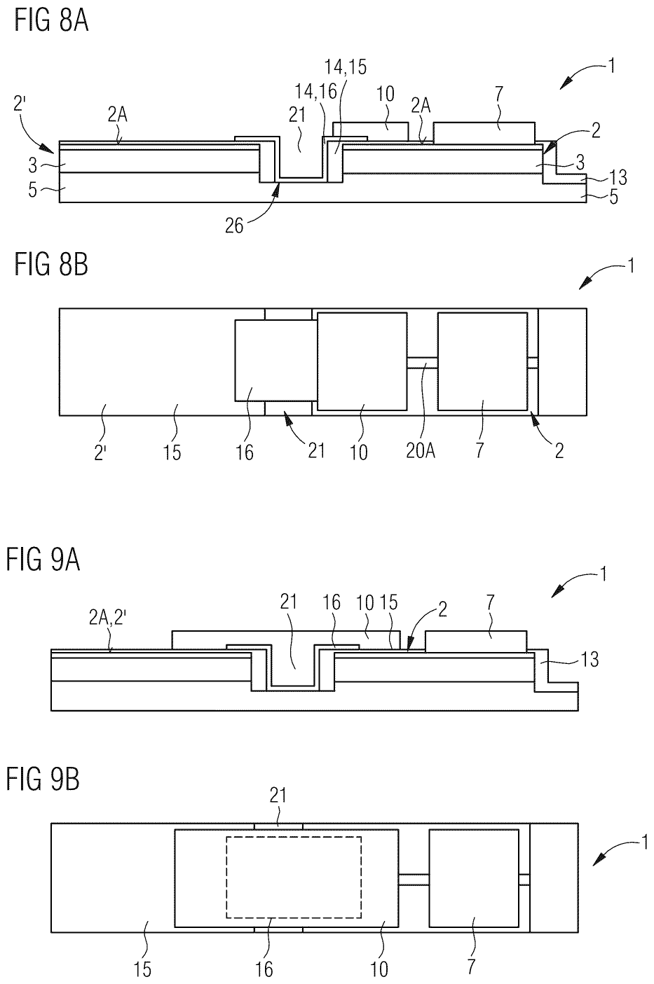

FIG. 8A shows a schematic cross-sectional view, and FIG. 8B shows a schematic top view of an exemplary embodiment of a laser diode component,

FIG. 9A shows a schematic cross-sectional view, and FIG. 9B shows a schematic top view of an exemplary embodiment of a laser diode component,

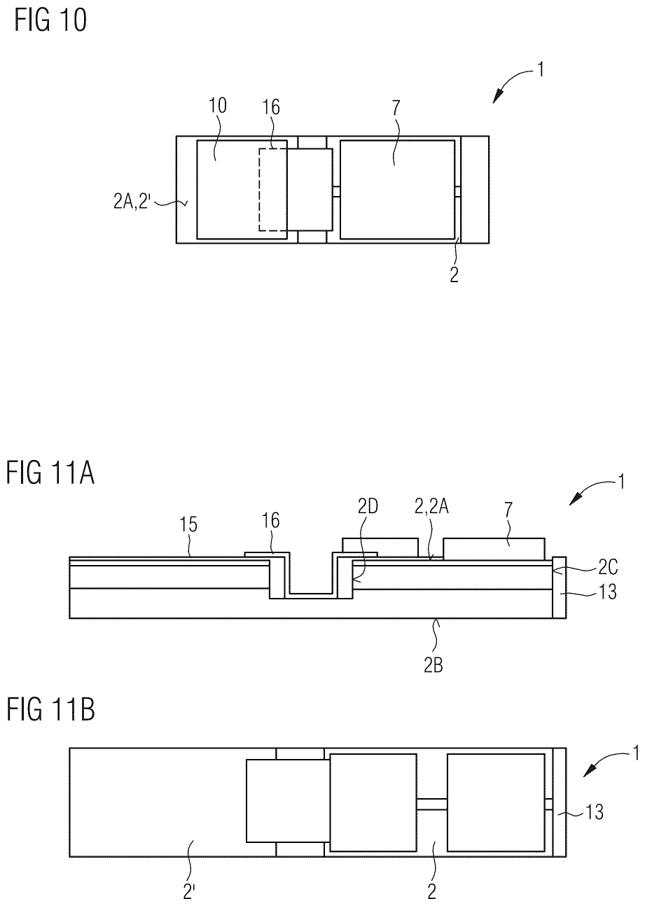

FIG. 10 shows a schematic top view of an exemplary embodiment of a laser diode component,

FIG. 11A shows a schematic cross-sectional view, and FIG. 11B shows a schematic top view of an exemplary embodiment of a laser diode component,

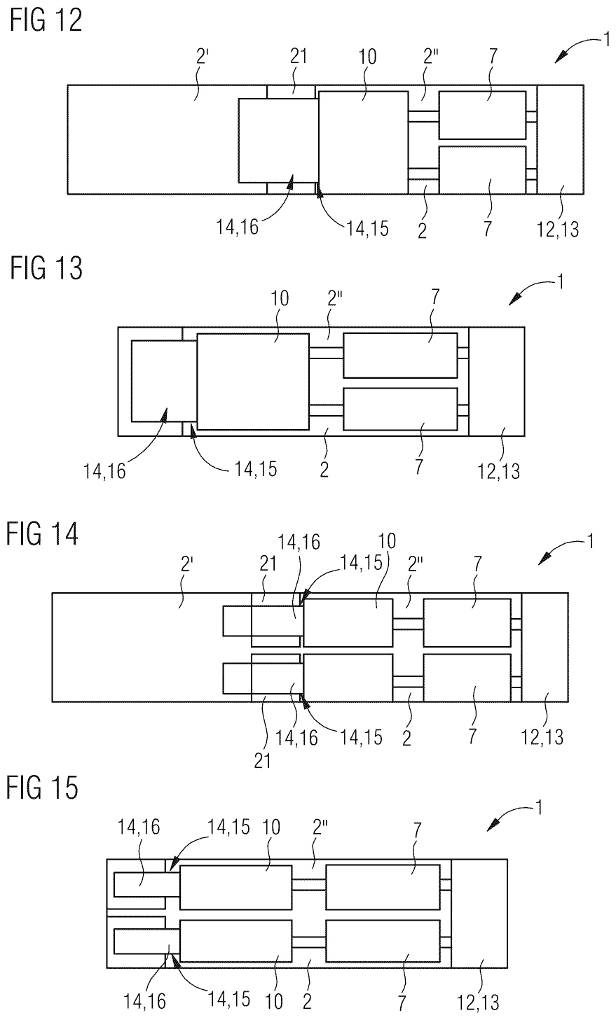

FIGS. 12 to 15 show schematic cross-sectional views of various exemplary embodiments of a laser diode component,

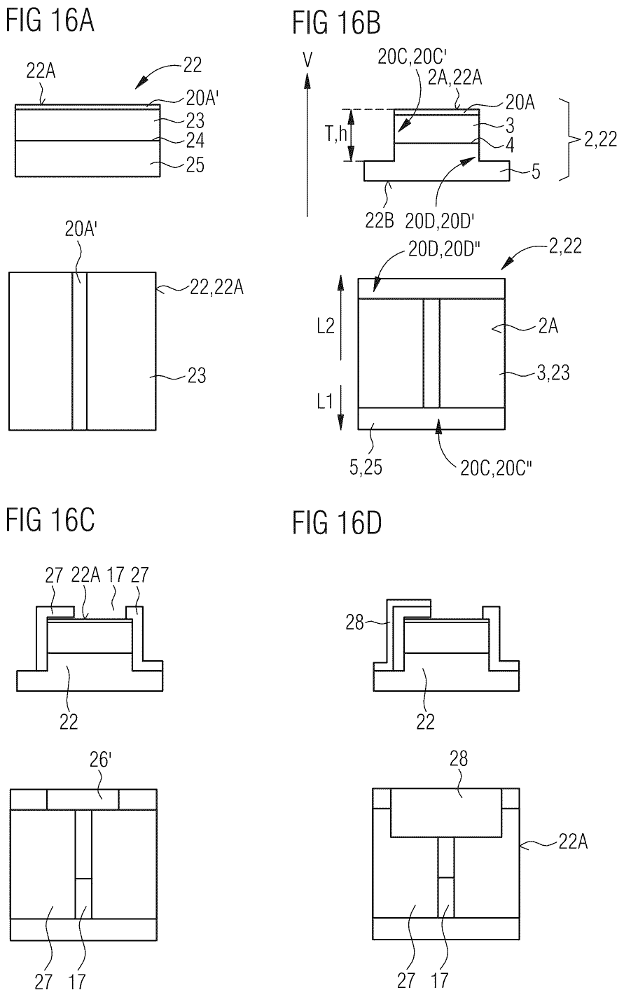

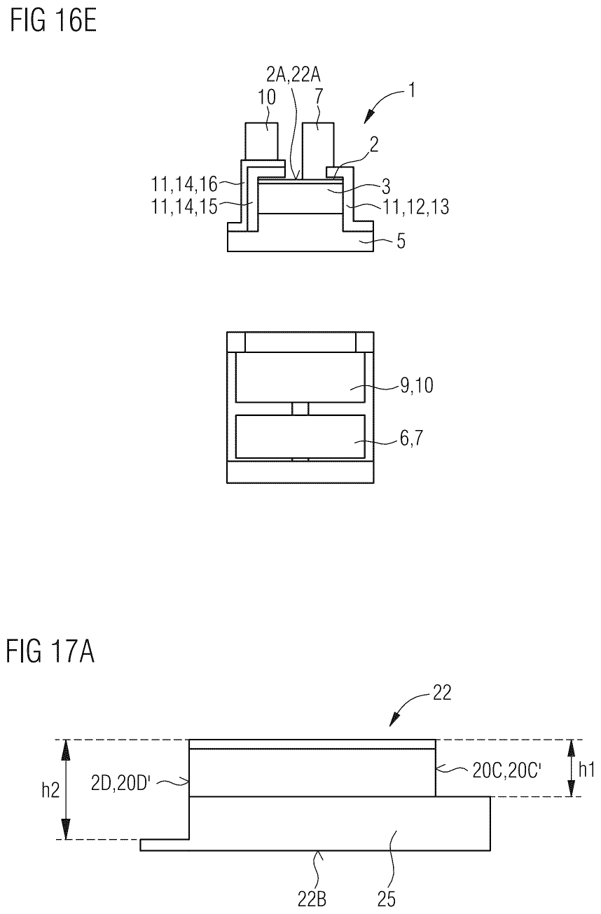

FIGS. 16A, top to 16E, top show schematic cross-sectional views, and FIGS. 16A, bottom to 16E, bottom show schematic plan views of various method steps of a method according to an exemplary embodiment,

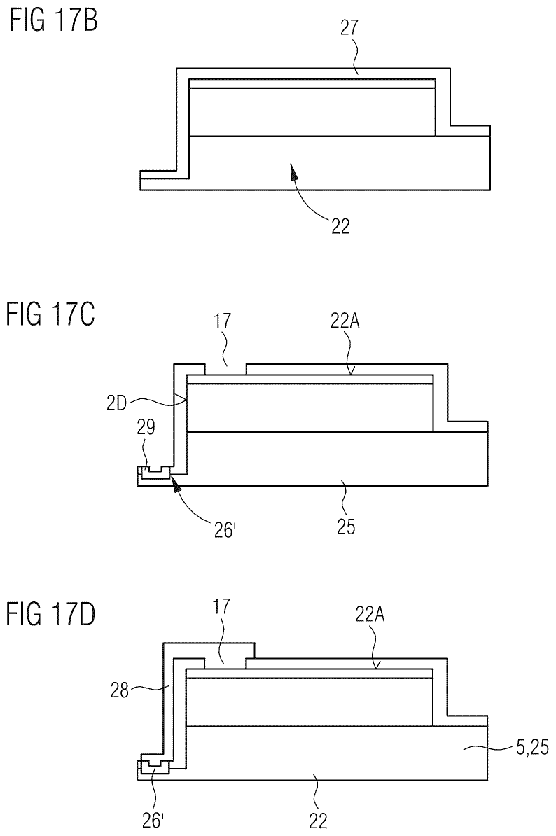

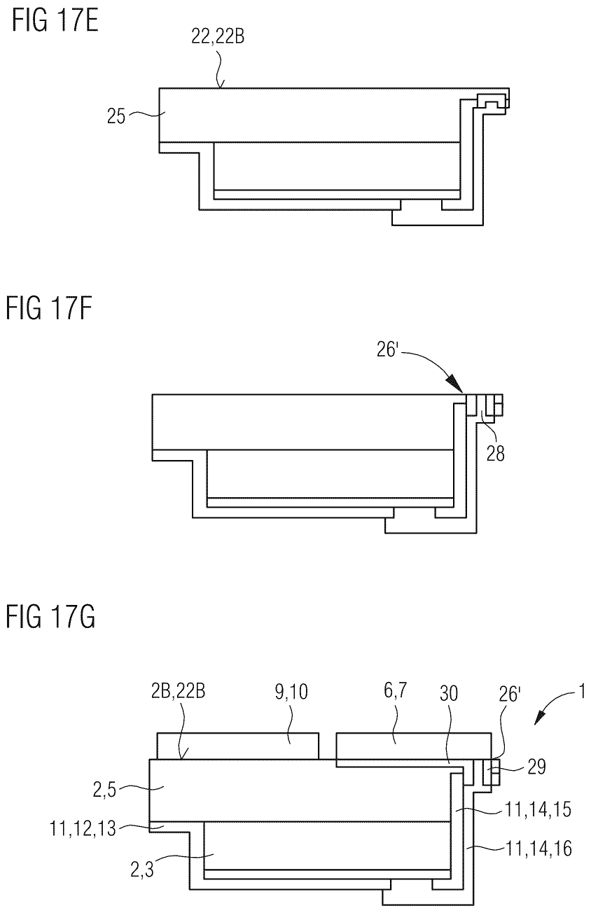

FIGS. 17A to 17G show schematic cross-sectional views of various method steps of a method according to a further exemplary embodiment, and FIG. 17G shows a schematic cross-sectional view of an exemplary embodiment of a laser diode component,

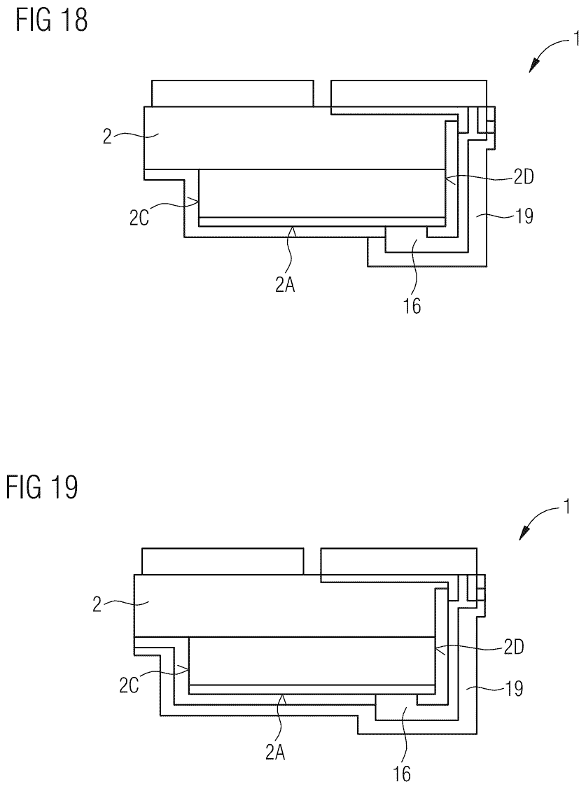

FIGS. 18 and 19 show schematic cross-sectional views of various exemplary embodiments of a laser diode component.

In the exemplary embodiments and figures, identical elements, elements of the same kind or elements having the same effect may each be provided with the same reference signs. The elements shown and their relative sizes are not necessarily to be regarded as true to scale; rather, individual elements may be shown in exaggerated size for better visualization and/or understanding.

In connection with FIGS. 1A to 1E, various exemplary embodiments of a laser diode component 1 are described. As shown in FIG. 1A, the laser diode component 1 comprises a semiconductor layer stack 2 comprising a first semiconductor region 3, for example a p-conducting semiconductor region, a second semiconductor region 5, for example an n-conducting semiconductor region, and an active zone 4 which is arranged between the first and second semiconductor regions 3, 5 and is configured to generate and emit laser radiation, for example in the ultraviolet to infrared spectral range, during operation. In a vertical direction V, the active zone 4 can follow the second semiconductor region 5, and the first semiconductor region 3 can follow the active zone 4, wherein the vertical direction V is, for example, a growth direction in which the semiconductor regions 3, 4, 5 are successively grown in an epitaxial manner on a growth substrate (not shown). The growth substrate can be completely removed or at least thinned after the semiconductor layer stack 2 has been produced. However, it is also possible for the growth substrate to remain in the laser diode component 1 as the carrier on which the semiconductor layer stack 2 is arranged, or for a different carrier (not shown) to be used.

For the semiconductor regions 3, 4, 5 or individual layers of the semiconductor layer stack 2, materials based on arsenide, phosphide or nitride compound semiconductors, for example, can be considered, as already mentioned above.

The semiconductor layer stack 2 has a first main surface 2A and a second main surface 2B opposite the first main surface 2A, as well as a first side surface 2C and a second side surface 2D opposite the first side surface 2C. Starting from the first main surface 2A and extending beyond the active zone 4, the first and second side surfaces 2C, 2D each extend transverse, in particular substantially perpendicular, to the first and second main surfaces 2A, 2B, each have a substantially horizontal section 20C″, 20D″ in the second semiconductor region 5 and each extend transverse, substantially perpendicular, to the first and second main surfaces 2A, 2B at the transition to the second main surface 2B. As a result, the semiconductor layer stack 2 comprises a first side region 20C which, in plan view of the laser diode component 1, protrudes beyond the first main surface 2A in a first lateral direction L1, and a second side region 20D which, in plan view of the laser diode component 1, protrudes beyond the first main surface 2A in a second lateral direction L2. The first and second lateral directions L1, L2 are arranged, for example, parallel to a main extension plane of the semiconductor layer stack 2 or laser diode component 1 and transverse, in particular substantially perpendicular, to the vertical direction V. The first and second main surfaces 2A, 2B may delimit the semiconductor layer stack 2 in directions substantially transverse, in particular substantially perpendicular, to the main extension plane of the semiconductor layer stack 2, while the first and second side surfaces 2C, 2D delimit the semiconductor layer stack 2 at least in regions in directions substantially parallel to the main extension plane of the semiconductor layer stack 2. For example, the first main surface 2A is a surface of the first semiconductor region 3, while the second main surface 2B is a surface of the second semiconductor region 5.

Further, the laser diode component 1 comprises a resonator 11 comprising a first resonator region 12 and a second resonator region 14, wherein the first resonator region 12 is arranged at the first side surface 2C and the second resonator region 14 is arranged at the second side surface 2D. The active zone 4 is arranged between the first and second resonator regions 12, 14.

In this case, the first resonator region 12 comprises a first reflective layer 13, which is arranged on the semiconductor layer stack 2 and extends on the first side surface 2C starting from the first protruding side region 20C to the first main surface 2A. Further, the second resonator region 14 comprises a first reflective layer 15 and a second, electrically conductive reflective layer 16, each arranged on the semiconductor layer stack 2 and extending on the second side surface 2D from the second protruding side region 20D to the first main surface 2A. In other words, the first and second reflective layers 15, 16 each extend from the second semiconductor region 5 over the second side surface 2D to the first main surface 2A, while the first reflective layer 13 extends over the first side surface 2C to the first main surface 2A.

The laser diode component 1 is, for example, an edge-emitting laser diode component 1 in which the laser radiation S is emitted substantially parallel to a plane of the active zone 4. In particular, the laser radiation S emerges from the laser diode component 1 on the side of the first side surface 2C, so that this side is a radiation outcoupling side. The laser diode component 1 can comprise a ridge structure 20A at the first main surface 2A for lateral wave guidance.

In the present disclosure, a “reflective layer” is understood to mean, for example, a layer which has a reflectivity of at least 10%, preferably of at least 20%, particularly preferably of at least 70% for the laser radiation generated in the active zone 4. For example, the first reflective layers 13, 15 can each comprise or consist of a dielectric layer or dielectric layer sequence. The first reflective layers 13, 15 may each comprise alternately arranged layers of a higher and a lower refractive index. For example, the first reflective layers 13, 15 are each a Bragg mirror.

Suitable materials for the dielectric layer or dielectric layer sequence are, for example, HfO, Zro, TaO, SiN, Sio, SiON, AlO, AlON, NbO. The first reflective layers 13, 15 can have the same material and layer structure. However, it is also possible for the first reflective layers 13, 15 to be formed from different materials and/or with different layer structures, for example to achieve different reflectivities.

The second reflective layer 16 can comprise a metallic layer or metallic layer sequence or consist of a metallic layer or metallic layer sequence. A “metallic layer” or a “metallic layer sequence” means, for example, a layer or layer sequence with metallic properties. For example, Ag, Ti, TiW, Rh, Au, Pt or combinations of these materials can be considered for the metallic layer or metallic layer sequence.

The second reflective layer 16 is arranged at least partially on a side of the first reflective layer 15 of the second resonator region 14 facing away from the semiconductor layer stack 2. In particular, the second reflective layer 16 is arranged in the second resonator region 14 on a side of the first reflective layer 15 facing away from the semiconductor layer stack 2.

The second resonator region 14 advantageously has a higher reflectivity for the laser radiation S than the first resonator region 12.

The diagrams in FIGS. 2A and 2B show calculated reflectivities R [%] as a function of the wavelength λ [nm] for a dielectric reflective layer (see FIG. 2A) and for a layer sequence consisting of a dielectric reflective layer and a reflective layer made of Ag (see FIG. 2B). While the reflectivity R of a dielectric reflective layer is 80% at 445 nm, it can be increased to about 99% by covering it with an Ag layer. Accordingly, the reflectivity of the second resonator region 14 can be increased by the second reflective layer 16 compared to the first resonator region 12.

For example, the first resonator region 12 may have a reflectivity of between 70% and 80% in a wavelength range of 410 nm to 470 nm, while the second resonator region 14 may have a reflectivity of at least 95% in this wavelength range.

The laser diode component 1 comprises a first contact structure 6 for electrically contacting the first semiconductor region 3, said first contact structure comprising a first contact element 7, and a second contact structure 9 for electrically contacting the second semiconductor region 5, said second contact structure comprising a second contact element 10, wherein the first and second contact elements 7, 10 are arranged on the first main surface 2A and thus on the same side of the semiconductor layer stack 2 or laser diode component 1. By arranging the contact elements 7, 10 on the same side, a flip-chip design is realized in the laser diode component 1.

In addition, the first contact structure 6 comprises a contact layer 8, which is arranged between the first semiconductor region 3 and the first contact element 7 and improves an electrical contact. Materials with comparatively good electric conductivity such as Pd, Pt, Rh, ITO, Ni, Rh, Zno or combinations thereof are suitable for the contact layer 8.

The first and second contact elements 7, 10 can comprise or be made of electrically conductive materials such as Ti, Pt, Au, Zno, TiW, Pd, Rh or combinations thereof.

Furthermore, the second reflective layer 16 is arranged between the second contact element 10 and the semiconductor layer stack 2. By means of the second, electrically conductive reflective layer 16, the second contact element 10 is electrically conductively connected to the second semiconductor region 5. The second, electrically conductive reflective layer 16 thus establishes an electrical connection between the semiconductor region 5, which is further away from the side on which the contact elements 7, 10 are located, and the associated contact element 10.

The second, electrically conductive reflective layer 16 is part of the second contact structure 9. By using the second reflective layer 16 as an electrical connection layer, the laser diode component 1 can be realized in a simple manner with a flip-chip design.

The first reflective layers 13, 15 can each be electrically weakly conducting or electrically insulating. As a result, the first reflective layer 15 can have the function of an insulation layer, which electrically insulates a pn junction of the active zone 4 from the electrically conductive second reflective layer 16.

The first reflective layers 13, 15 are spaced from each other at the first main surface 2A by a gap 17 in which the first contact element 7 is arranged. The first reflective layers 13, 15 can form a continuous layer, so that all regions of the first reflective layers 13, 15 are connected to one another.

The semiconductor layer stack 2 can have an approximately cuboidal shape and thus four side surfaces 2C, 2D, 2E, 2F (see FIG. 1B). All four side surfaces 2C, 2D, 2E, 2F can be partially or completely covered by at least one first reflective layer 13, 15 or by the continuous layer.

The semiconductor layer stack 2 comprises structured regions with etching traces (not shown) at the first and second side surfaces 2C, 2D in parts covered by the resonator regions 12, 14. In particular, the etching traces are the result of producing the semiconductor layer stack 2 by etching. By producing by etching, as described in more detail in connection with FIGS. 16A to 16E, the reflective layers 13, 15, 16 can already be applied to the semiconductor layer stack 2 in a wafer composite. A preceding splitting of the wafer composite, for example by breaking, to produce the side surfaces 2C, 2D is not necessary, which makes the production process less complex as a whole.

FIGS. 1B to 1E show various configurations of the second reflective layer 16 and the contact elements 7, 10, as may be realized in the laser diode component 1 described in connection with FIG. 1A.

Here, a lateral extension a1 of the second reflective layer 16 is in each case greater than a lateral extension a2 of the ridge structure 20A and less than a lateral extension a3 of the second side surface 2D, the lateral extensions a1, a2, a3 being determined in each case along a third lateral direction L3, which runs transverse to the first and second lateral directions L1, L2 and to the vertical direction V.

Furthermore, the first and second contact elements 7, 10 are arranged next to each other in plan view of the first main surface 2A. The first and second contact elements 7, 10 can each be strip-shaped (see FIGS. 1B and 1C). It is also possible that the first and second contact elements 7, 10 are each L-shaped (see FIGS. 1D and 1E). In this case, the L-shaped contact elements 7, 10 can be oriented with respect to each other in such a way that they are arranged as compactly as possible. The first and second contact elements 7, 10 can be positioned and designed in such a way that mounting or electrical contacting of the laser diode component 1 on a connection carrier can be carried out easily and reliably.

In the configurations of FIGS. 1B to 1E, the contact elements 7, 10 each extend transverse at least in regions, in particular substantially perpendicular at least in regions, to the ridge structure 20A, so that the latter is covered by the respective contact elements 7, 10 in regions. This allows the reflectivity on the ridge structure 20A to be increased.

The laser diode component 1 described in connection with FIGS. 1A to 1E may furthermore have all the features and advantages mentioned in connection with the other exemplary embodiments.

Further exemplary embodiments and configurations are described with reference to FIGS. 3A to 3C and 3D to 3F. In comparison to the exemplary embodiments of FIGS. 1A to 1E, the second contact element 10 in these exemplary embodiments extends beyond the first main surface 2A to at least one side surface.

In addition to the first and second side regions 20C, 20D, the laser diode component 1 can comprise a third side region 20E, which protrudes beyond the first main surface 2A in the third lateral direction L3 in plan view of the laser diode component 1 (see FIG. 3A). The second reflective layer 16 can also be applied to the third side region 20E (see FIG. 3B). Starting from the second semiconductor region 5 of the third side region 20E, the second reflective layer 16 can extend over the third side surface 2E to the first main surface 2A. Furthermore, the second reflective layer 16 can extend in lateral directions over the second and third side surfaces 2D, 2E. The electrical connection between the second semiconductor region 5 and the second contact element 10 can thus be improved.

Furthermore, the laser diode component 1 may additionally comprise a fourth side region 20F which, in plan view of the laser diode component 1, projects beyond the first main surface 2A in a fourth lateral direction L4 which extends transverse, in particular substantially perpendicular to the first and second lateral directions L1, L2 (see FIGS. 3D to 3F). The second reflective layer 16 can also be applied to the fourth side region 20F (see FIGS. 3D to 3F). Starting from the second semiconductor region 5 of the fourth side region 20E, the second reflective layer 16 can extend over the fourth side surface 2F to the first main surface 2A. Furthermore, the second reflective layer 16 can extend laterally over the second, third and fourth side surfaces 2D, 2E, 2F. The electrical connection between the second semiconductor region 5 and the second contact element 10 can thus be further improved.

While the first contact element 7 is arranged only on the first main surface 2A, in particular on the ridge structure 20A, the second contact element 10 extends from the first main surface 2A to several side surfaces or side regions. In the exemplary embodiment shown in FIG. 3C, the second contact element 10 extends to the second and third side regions 20D, 20E and, in the exemplary embodiments shown in FIGS. 3D to 3F, also to the fourth side region 20F. The second contact element 10 can be designed as a continuous region in plan view of the laser diode component 1, for example in the form of a strip or U-shape (see FIGS. 3C, 3E, 3F) or discontinuously in the form of two strips (see FIG. 3D).

The laser diode component 1 described in connection with FIGS. 3A to 3F may furthermore have all the features and advantages mentioned in connection with the other exemplary embodiments.

With reference to FIG. 4, a further exemplary embodiment of a laser diode component 1 is described. Here, the semiconductor region further away from the contact elements 7, 10, such as the second semiconductor region 5, comprises a layer 18 with higher doping than the rest of the semiconductor region. In particular, the highly doped, for example n++ layer 18 is directly adjacent to the second reflective layer 16. This can improve the electrical contact.

The laser diode component 1 described in connection with FIG. 4 may furthermore have all the features and advantages mentioned in connection with the other exemplary embodiments.

Further exemplary embodiments of a laser diode component 1 are described with reference to FIGS. 5 to 7. Here, the laser diode component 1 comprises a passivation layer 19, which is provided, for example, to protect the second reflective layer 16, which may be formed from a comparatively reactive material such as Ag. The passivation layer 19 can be a dielectric layer, for which materials such as Sio, SiN, SiON, Zro, DLC (diamond-like carbon), SiC, AlN, HfO and NbO can be considered.

As shown in FIG. 5, the passivation layer 19 can be arranged on the first reflective layer 15 or second reflective layer 16 of the second resonator region 14 and extend from the second semiconductor region 5 of the second side region 20D via the second side surface 2D to the first main surface 2A.

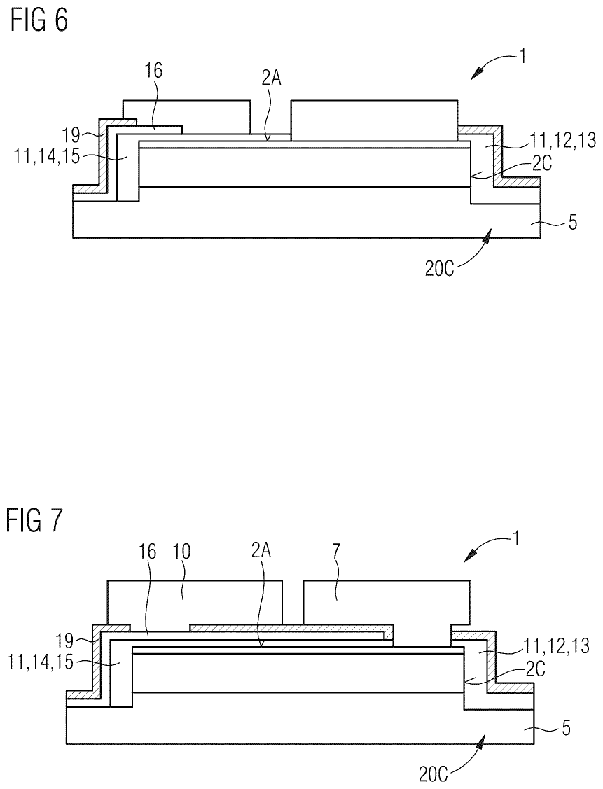

As shown in FIG. 6, the passivation layer 19 may also be arranged on the first reflective layer 13 of the first resonator region 12 and extend from the second semiconductor region 5 of the first side region 20C via the first side surface 2C to the first main surface 2A. The passivation layer 19 can change the reflectivity of the first resonator region 12, so that this must be taken into account accordingly when designing the resonator 11.

As shown in FIG. 7, the second reflective layer 16 can extend below the first contact element 7. This can offer advantages in terms of heat dissipation or enable other designs of the contact elements 7, 10 and thus simplify assembly. The passivation layer 19 can be arranged below the first and second contact elements 7, 10 and form an electrical insulation between the second reflective layer 16 and the first contact element 7.

The laser diode component 1 described in connection with FIGS. 5 to 7 may furthermore have all the features and advantages mentioned in connection with the other exemplary embodiments.

With reference to FIGS. 8A to 11B further exemplary embodiments of a laser diode component 1 are described. Here, the laser diode component 1 comprises two semiconductor layer stacks 2, 2′, which are spaced from each other by a gap 21. The gap 21 extends into the second semiconductor regions 5, which are designed continuously, and separates the first semiconductor regions 3 from one another.

Only one of the two semiconductor layer stacks 2, 2′ is provided for generating laser radiation. The second resonator region 14 of the semiconductor layer stack 2 intended for radiation emission is arranged in the gap 21. The second resonator region 14 therefore does not have to be arranged on an outer side of the laser diode component 1 as in the preceding exemplary embodiments but can also be located inside it. This can have advantages if very short resonator lengths are to be produced but larger components are required, as components that are too small are difficult to handle during assembly and measurement processes.

The first reflective layer 15 of the second resonator region 14 is arranged on the first main surfaces 2A of the semiconductor layer stacks 2, 2′ and in the gap 21, the first reflective layer 15 comprising an opening 26 in the gap 21 for the second reflective layer 16 for electrical contacting of the second semiconductor region 5. The second reflective layer 16 extends from the first main surface 2A of the semiconductor layer stack 2 intended for radiation emission through the gap 21 to the first main surface 2A of the other semiconductor layer stack 2′.

As in the exemplary embodiment shown in FIGS. 8A and 8B, the first and second contact elements 7, 10 may be arranged on the first main surface 2A of the semiconductor layer stack 2 provided for radiation emission.

However, it is also possible that the second contact element 10 extends to the first main surface 2A of the other semiconductor layer stack 2′ and fills the gap 21 (see FIGS. 9A and 9B). Furthermore, it is possible that the second contact element 10 is arranged only on the first main surface 2A of the semiconductor layer stack 2′ not intended for radiation emission (see FIG. 10). Arrangements of this kind of the second contact element 10 can solve space problems with small components and resonator lengths.

While the second side surface 2D of the semiconductor layer stack 2 intended for radiation emission is preferably etched, the first side surface 2C of the semiconductor layer stack 2 intended for radiation emission can be broken and thereby extend substantially transverse, in particular substantially perpendicular to the first and second main surfaces 2A, 2B (see FIGS. 11A and 11B). This has the advantage of improving the quality of the first side surface 2C if the etching process causes problems. While the first and second reflective layers 15, 16 can be produced in a wafer composite, it is possible to produce the first reflective layer 13 by sputtering on the broken side surface 2C. This can offer advantages in terms of component reliability.

The laser diode component 1 described in connection with FIGS. 8 to 11 may furthermore have all the features and advantages mentioned in connection with the other exemplary embodiments.

With reference to FIGS. 12 to 15, further exemplary embodiments of a laser diode component 1 are described. Here, the laser diode component 1 comprises two semiconductor layer stacks 2, 2″ intended for radiation emission, which are provided with a common first resonator region 12. Furthermore, the laser diode component 1 can comprise a semiconductor layer stack 2′ not intended for radiation emission. The semiconductor layer stacks 2, 2″ provided for radiation emission can each be spaced from the semiconductor layer stack 2′ not provided for radiation emission by a continuous (see FIG. 12) or interrupted (see FIG. 14) gap 21 (see FIGS. 12, 14).

The second resonator regions 14 can form a common region (see FIGS. 12 and 13) or be separate regions (see FIGS. 14 and 15). While a separate first contact element 7 is provided for each semiconductor layer stack 2, 2″, in particular a common second reflective layer 16 and a common second contact element 10 can be provided in the case of a common second resonator region 14. In the case of separate second resonator regions 14, the second reflective layers 16 and contact elements 10 can be formed separately.

The laser diode component 1 described in connection with FIGS. 12 to 15 may furthermore have all the features and advantages mentioned in connection with the other exemplary embodiments.

With reference to FIGS. 16A to 16E, a first exemplary embodiment of a method suitable for producing a laser diode component 1 as described, for example, in connection with the preceding figures is described. The upper figures show schematic cross-sectional views. The lower figures show in each case the corresponding schematic top views.

The method comprises a step of providing a semiconductor layer sequence 22 comprising a first semiconductor layer 23, a second semiconductor layer 25, and an active layer 24 arranged between the first semiconductor layer 23 and the second semiconductor layer 25 (see FIG. 16A). At a first surface 22A, the semiconductor layer sequence 22 can comprise a ridge structure 20A′, which can be produced by etching.

Furthermore, the method comprises a step of structuring the semiconductor layer sequence 22, wherein at least one semiconductor layer stack 2 is produced, which comprises a first semiconductor region 3, a second semiconductor region 5, and an active zone 4 arranged between the first and second semiconductor regions 3, 5 for emitting laser radiation (see FIG. 16B).

In terms of its layer structure and material composition, the semiconductor layer sequence 22 corresponds to the semiconductor layer stack 2 that is produced from it, so that what has been specified in this regard applies accordingly to the semiconductor layer sequence 22. In particular, the first semiconductor region 3 is formed from the first semiconductor layer 23, the active zone 4 is formed from the active layer 24, and the second semiconductor region 5 is formed from the second semiconductor layer 25. The semiconductor layer sequence 22 can be provided on a substrate (not shown) on which it is grown epitaxially, for example.

The semiconductor layer sequence 22 is preferably structured by means of etching, wherein at least a part of a first side surface 2C and at least a part of a second side surface 2D of the semiconductor layer stack 2 are produced when etching. The etching step may, for example, include a first etching process, which in particular includes a plasma etching process using chlorine and argon ions, a laser ablation process or a photochemical wet etching process. The etching step may further include a second etching process in which, in particular, wetchemical etching is carried out using, for example, KOH, NaOH, NH₄OH, LiOH, TMAH, NMP (N-methyl-2-pyrrolidone) and preferably the first and second side surfaces 2C, 2D are smoothed. By means of the second etching process, crystal planes of the material system used for the semiconductor layer sequence 22 can be carved out, which are particularly suitable as laser facets.

In particular, the structuring or etching of the semiconductor layer sequence 22 is carried out starting from the first surface 22A or a side of the first semiconductor layer 23 facing away from the second semiconductor layer 25 in the direction of a second surface 22B opposite the first surface through the semiconductor layer sequence 22 and into the second semiconductor layer 25. Here, a depth T of the structuring determines a vertical extension h of a vertical section 20C′, 20D′ of the respective side surface 2C, 2D. The depth T or vertical extension h indicates an extension substantially perpendicular to the main extension plane of the semiconductor layer stack 2 or parallel to the vertical direction V, which can be a growth direction in which the layers 25, 24, 23 are grown one after the other.

The semiconductor layer sequence 22 is not completely penetrated during structuring, so that the first and second side surfaces 2C, 2D in the second semiconductor layer 25 or in the second semiconductor region 5, respectively, each comprise a substantially horizontal section 20C″, 20D″. As a result, the semiconductor layer stack 2 can comprise a first side region 20C which, in plan view, projects beyond the first main surface 2A in a first lateral direction L1, and a second side region 20D which, in plan view, projects beyond the first main surface 2A in a second lateral direction L2.

A contact layer can be produced on a first main surface 2A of the semiconductor layer stack 2 (not shown, but see contact layer 8 in FIG. 1A).

Further, the method comprises a step of applying a first initial reflective layer 27 on the semiconductor layer sequence 22 for producing first reflective layers 13, 15 of a first resonator region 12 and a second resonator region 14 of at least one resonator 11 of a laser diode component 1 (see FIGS. 16C and 16E). The first initial reflective layer 27 can be applied without interruptions and subsequently structured so that it comprises at least one gap 17 for a first contact element 7 of a laser diode component 1 and at least one opening 26′ for a second reflective layer 16 of a laser diode component 1. The first initial reflective layer 27 can protect the ridge structure 20A′ so that no further passivation is necessary. However, it is possible to arrange a passivation on the ridge structure 20A′ before applying the initial reflective layer 27.

The method further comprises a step of applying a second, electrically conductive initial reflective layer 28 on the semiconductor layer sequence 22 to produce a second, electrically conductive reflective layer 16 of a second resonator region 14 of a laser diode component 1 (see FIGS. 16D and 16E). Here, the initial reflective layer 28 is applied such that it is arranged in the opening 26′ and extends to the first surface 22A. The second initial reflective layer 28 is arranged on the semiconductor layer sequence 22 in such a way that it can electrically conductively connect a second contact element 10 to the second semiconductor region 5 (see FIG. 16E).

The first initial reflective layer 27 corresponds, in particular with regard to its layer structure and its material composition, to the first reflective layers 13, 15 which are produced from it, so that what has been specified in this regard applies accordingly to the first initial reflective layer 27. Furthermore, the second initial reflective layer 28 corresponds, in particular with regard to its layer structure and its material composition, to the second reflective layer 16 which is produced from it, so that what has been specified in this regard applies accordingly to the second initial reflective layer 28.

The method further comprises a step of producing at least one first contact element 7 of at least one first contact structure 6 for electrically contacting the first semiconductor region 3 and at least one second contact element 10 of at least one second contact structure 9 for electrically contacting the second semiconductor region 5 of at least one laser diode component 1, wherein the two contact elements 7, 10 are arranged on the same side of the semiconductor layer stack 2, for example on the first main surface 2A or first surface 22A (see FIG. 16E).

The steps described in connection with FIGS. 16A to 16E may be performed in a wafer composite. After the step described in connection with FIG. 16E, the wafer composite may be singulated to form a plurality of laser diode components 1 which may have a cross-sectional view as shown in FIG. 16E.

The method described in connection with FIGS. 16A to 16E or the resulting laser diode component 1 may furthermore have all the features and advantages mentioned in connection with the other exemplary embodiments.

With reference to FIGS. 17A to 17G, a second exemplary embodiment of a method is described suitable for producing a laser diode component 1 in which the contact elements are arranged on a different side than in the preceding exemplary embodiments.

The method comprises a step of providing a semiconductor layer sequence 22 (see FIG. 17A), which can be structured by means of etching as described in connection with FIG. 16B. In this process, the semiconductor layer sequence 22 is etched deeper in the region of the second side surface 2D to be produced than in the region of the first side surface 2C to be produced, so that a vertical extension hl of a vertical section 20C′ of the first side surface 2C is smaller than a vertical extension h2 of a vertical section 20D′ of the second side surface 2D. Preferably, the second semiconductor layer 25 is largely penetrated when structuring the semiconductor layer sequence 22, so that the second reflective layer 16 to be produced can be contacted from the second main surface 2B in the finished laser diode component 1.

Further, the method comprises a step of applying a first initial reflective layer 27 on the semiconductor layer sequence 22 to form first reflective layers 13, 15 of a first resonator region 12 and a second resonator region 14 of at least one resonator 11 of a laser diode component 1 (see FIGS. 17B and 17G). The first initial reflective layer 27 can be applied without interruptions.

Subsequently, the first initial reflective layer 27 can be structured so that it comprises at least one gap 17 at the first surface 22A and at least one opening 26′ at the second side surface 2D in the second semiconductor region 25 for the second reflective layer 16 of a laser diode component 1 to be produced (see FIG. 17G). An insulating layer 29, for example made of a dielectric material, can be arranged in the opening 26′ (see FIG. 17C).

The method further comprises a step of applying a second, electrically conductive initial reflective layer 28 to the semiconductor layer sequence 22 to produce the second, electrically conductive reflective layer 16 (see FIG. 17D). The initial reflective layer 28 is applied in such a way that it is arranged in the openings 17, 26′ and extends from the second semiconductor layer 25 or the second semiconductor region 5 to the first surface 22A.

While the method steps described in connection with FIGS. 17A to 17D are carried out on or starting from the side of the first surface 22A, the method steps described in connection with FIGS. 17E to 17G are carried out on or starting from the side of the second surface 22B.

The method comprises a step of turning around the semiconductor layer sequence 22 or rebonding the wafer (see FIG. 17E).

Further, the method comprises a step of removing the second semiconductor layer 25 starting from the second surface 22B so that the initial reflective layer 28 is exposed in the opening (see FIG. 17F).

Finally, the method comprises a step of producing at least one first contact element 7 of at least one first contact structure 6 for electrically contacting the first semiconductor region 3 and at least one second contact element 10 of at least one second contact structure 9 for electrically contacting the second semiconductor region 5 of at least one laser diode component 1, wherein the two contact elements 7, 10 are arranged on the same side of the semiconductor layer sequence 22 or of the semiconductor layer stack 2, namely on the second surface 22B or second main surface 2B (see FIG. 17E). In this case, the first contact element 7 is arranged in contact with the second initial reflective layer 28 or reflective layer 16. Between the first contact element 7 and the second semiconductor region 5, a further insulating layer 30 can be arranged, which, together with the insulating layer 29 in the opening 26′ and the first reflective layer 15, electrically insulates the second reflective layer 16 from the second semiconductor region 5.

The steps described in connection with FIGS. 17A to 17G can be performed in the wafer composite. After the step described in connection with FIG. 17G, the wafer composite can be singulated to form a plurality of laser diode components 1.

The method described in connection with FIGS. 17A to 17G or the resulting laser diode component 1 may furthermore have all the features and advantages mentioned in connection with the other exemplary embodiments.

With reference to FIGS. 18 and 19, further exemplary embodiments of a laser diode component 1 are described that can be produced, for example, using the method according to the second exemplary embodiment. Here, as already explained in more detail in connection with FIGS. 5 to 7, a passivation layer 19 can be arranged on the semiconductor layer stack 2, said passivation layer covering the second reflective layer 16 and protecting it (see FIG. 18). The passivation layer 19 can extend from the second side surface 2D over the first main surface 2A to the first side surface 2C (see FIG. 19).

The laser diode component 1 described in connection with FIGS. 18 and 19 may furthermore have all the features and advantages mentioned in connection with the other exemplary embodiments.

The invention is not limited by the description based on the exemplary embodiments. Rather, the invention includes any new feature as well as any combination of features, which includes in particular any combination of features in the patent claims, even if this feature or combination itself is not explicitly stated in the patent claims or exemplary embodiments.

This patent application claims the priority of the German patent application 102022115644.3, the disclosure content of which is hereby incorporated by reference.

### LIST OF REFERENCES

1 laser diode component
2, 2″ semiconductor layer stack
2A first main surface
2B second main surface
2C first side surface
2D second side surface
2E third side surface
2F fourth side surface
2′ semiconductor layer stack not intended for radiation emission
3 first semiconductor region
4 active zone
5 second semiconductor region
6 first contact structure
7 first contact element
8 contact layer
9 second contact structure
10 second contact element
11 resonator
12 first resonator region
13 first reflective layer
14 second resonator region
15 first reflective layer
16 second reflective layer
17 gap
18 layer with higher doping
19 passivation layer
20A, 20A′ ridge structure
20C first side region
20C′ vertical section
20C″ horizontal section
20D second side region
20D′ vertical section
20D″ horizontal section
20E third side region
20F fourth side region
21 gap
22 semiconductor layer sequence
22A first surface
22B second surface
23 first semiconductor layer
24 active layer
25 second semiconductor layer
26, 26′ opening
27 first initial reflective layer
28 second initial reflective layer
29, 30 insulating layer
a1, a2, a3 lateral extension
h, h1, h2 vertical extension
L1 first lateral direction
L2 second lateral direction
L3 third lateral direction
L4 fourth lateral direction
S radiation
T depth
V vertical direction

1. A laser diode component comprising
at least one semiconductor layer stack comprising a first semiconductor region, a second semiconductor region, and an active zone arranged between the first and second semiconductor regions for emitting laser radiation,
at least one first contact structure for electrically contacting the first semiconductor region, said first contact structure comprising at least one first contact element, at least one second contact structure for electrically contacting the second semiconductor region, said second contact structure comprising at least one second contact element, wherein the at least one second contact element is arranged on the same side of the laser diode component as the at least one first contact element, and
at least one resonator comprising
a first resonator region comprising a first reflective layer arranged on the at least one semiconductor layer stack,
a second resonator region comprising a first reflective layer and a second, electrically conductive reflective layer, each arranged on the at least one semiconductor layer stack, wherein
the second, electrically conductive reflective layer electrically conductively connects the at least one first contact element to the first semiconductor region or the at least one second contact element to the second semiconductor region.

2. The laser diode component according to claim 1, wherein the at least one semiconductor layer stack comprises a first main surface and a second main surface opposite the first main surface, as well as a first side surface and a second side surface opposite the first side surface, each extending transverse to the first and second main surfaces at least in regions, and the first resonator region is arranged at the first side surface and the second resonator region is arranged at the second side surface.

3. The laser diode component according to claim 1, wherein the first reflective layer of the first resonator region and the first reflective layer of the second resonator region form a continuous layer.

4. The laser diode component according to claim 3, wherein the continuous layer is arranged on all side surfaces of the at least one semiconductor layer stack.

5. The laser diode component according to claim 2, wherein the at least one semiconductor layer stack comprises etching traces at the second side surface in parts covered by the second resonator region.

6. The laser diode component according to claim 1, wherein the first reflective layers are spaced from each other at the first main surface by a gap, in which the at least one first contact element or a part of the second reflective layer is arranged.

7. The laser diode component according to claim 1, wherein the first reflective layers each comprise a dielectric layer or dielectric layer sequence.

8. The laser diode component according to claim 1, wherein the second reflective layer comprises a metallic layer or metallic layer sequence.

9. The laser diode component according to claim 1, wherein the second resonator region has a higher reflectivity for the laser radiation than the first resonator region.

10. The laser diode component according to claim 1, wherein the second reflective layer is arranged at least partially on a side of the first reflective layer of the second resonator region facing away from the semiconductor layer stack.

11. The laser diode component according to claim 2, wherein the second reflective layer extends from the second semiconductor region over the second side surface to the first main surface.

12. The laser diode component according to claim 1, wherein the at least one first and second contact elements are arranged on the first main surface or on the second main surface.

13. The laser diode component according to claim 1, comprising at least two semiconductor layer stacks spaced from each other by a gap.

14. The laser diode component according to claim 1, comprising at least two semiconductor layer stacks provided with a common first resonator region.

15. A method for producing at least one laser diode component according to claim 1, comprising:
providing a semiconductor layer sequence comprising a first semiconductor layer, a second semiconductor layer, and an active layer arranged between the first semiconductor layer and the second semiconductor layer,
structuring the semiconductor layer sequence, wherein at least one semiconductor layer stack is produced, which comprises a first semiconductor region, a second semiconductor region, and an active zone arranged between the first and second semiconductor regions for emitting laser radiation,
applying at least one first initial reflective layer on the semiconductor layer sequence for producing first reflective layers of a first resonator region and a second resonator region of at least one resonator of at least one laser diode component,
applying at least one second, electrically conductive initial reflective layer on the semiconductor layer sequence for producing at least one second, electrically conductive reflective layer of the second resonator region of at least one resonator of at least one laser diode component,
producing at least one first contact element of at least one first contact structure for electrically contacting the first semiconductor region and at least one second contact element of at least one second contact structure for electrically contacting the second semiconductor region of at least one laser diode component, wherein the at least one second contact element is arranged on the same side of the at least one semiconductor layer stack as the at least one first contact element, and wherein the second initial reflective layer is arranged on the semiconductor layer sequence in such a way that it electrically conductively connects the at least one first contact element to the first semiconductor region or the at least one second contact element to the second semiconductor region,

16. The method according to claim 15, wherein the semiconductor layer sequence is structured by means of etching, and at least a part of a first side surface and at least a part of a second side surface of the at least one semiconductor layer stack are produced when etching.

17. The method according to claim 15, wherein the structuring of the semiconductor layer sequence is carried out starting from a side of the first semiconductor layer facing away from the second semiconductor layer through the semiconductor layer sequence and into the second semiconductor layer.

18. The method according to claim 15, wherein in the first initial reflective layer at least one gap is produced, in which the at least one first contact element or a part of the second initial reflective layer is arranged.
